(19) United States
(12) Patent Application Publication
(10) Pub. No.: US 2025/0338432 A1
(43) Pub. Date: Oct. 30, 2025

(54) ROTATING COLD PLATE ASSEMBLY, SYSTEM AND METHOD OF OPERATING COLD PLATE ASSEMBLY

(71) Applicant: ZT Group Int'l, Inc., Secaucus, NJ (US)

(72) Inventors: Sruti CHIGULLAPALLI, Seattle, WA (US); Paul Harold ANDERSON, Leander, TX (US)

(73) Assignee: ZT Group Int'l, Inc., Secaucus, NJ (US)

(21) Appl. No.: 18/644,354

(22) Filed: Apr. 24, 2024

(51) Int. Cl. H05K 7/20

(52) U.S. Cl. CPC H05K 7/20254

(57) ABSTRACT

Described herein is a rotating cold plate assembly that includes a base configured to be mounted to a printed circuit board (PCB) to at least partially surround an electronic circuit disposed on the PCB. The cold plate assembly further includes a cold plate having a heat transfer surface configured to transfer heat from the electronic circuit to a cooling medium. The cold plate assembly also includes a hinge coupling the base and the cold plate. The hinge is configured to move the heat transfer surface into and away from thermal contact with the electronic circuit.

### FIELD

This disclosure is directed to a cold plate assembly for an electronic component.

### BACKGROUND

Many electronic components (e.g., circuits, processors, systems-on-chips (SOCs), amplifiers) are configured to interface with cold plates (e.g., heat sinks and liquid cooling plates) to dissipate heat generated by the electronic components. Often times, thermal interface materials (TIMs) are disposed between the electronic components and the cold plates to facilitate heat transfer. Performances of TIMs degrade over time, however, which results in TIM lifespans that are far shorter than the electronic components they interface with. Accordingly, TIMs are replaced on a periodic basis to ensure proper performance of the electronic components. Replacing TIMs can be a time consuming task, especially in the case of liquid-cooling cold plates.

### SUMMARY

A cold plate assembly is described herein. The cold plate assembly includes a base configured to be mounted to a printed circuit board (PCB) to at least partially surround an electronic circuit (or component) disposed on the PCB. The cold plate assembly further includes a cold plate having a heat transfer surface configured to transfer heat from the electronic circuit to a cooling medium. The cold plate assembly also includes a hinge coupling the base and the cold plate. The hinge is configured to move the heat transfer surface into and away from thermal contact with the electronic circuit.

A system is also described herein. The system includes a PCB and an electronic circuit disposed on the PCB. The system further includes a cold plate assembly having a base mounted to the PCB that at least partially surrounds the electronic circuit disposed on the PCB. The cold plate assembly also has a cold plate with a heat transfer surface configured to transfer heat from the electronic circuit to a cooling medium. The cold plate assembly further has a hinge connecting the base and the cold plate. The hinge is configured to move the heat transfer surface into and away from thermal contact with the electronic circuit.

A method of operating a cold plate assembly is also described herein. The cold plate assembly contains a base mounted to a PCB that at least partially surrounds an electronic circuit disposed on the PCB. The cold plate assembly also contains a cold plate with a heat transfer surface configured to transfer heat from the electronic circuit to a cooling medium. The cold plate assembly further contains a hinge connecting the base and the cold plate. The method includes operating the hinge to move the heat transfer surface away from thermal contact with the electronic circuit. The method also includes arranging a TIM on at least one of the heat transfer surface of the cold plate and the electronic circuit. The method further includes operating the hinge to move the heat transfer surface into thermal contact with the electronic circuit via the TIM.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a system containing a rotating cold plate assembly, in accordance with various examples of the present disclosure.

FIG. 2 illustrates an example of a rotating cold plate assembly with a first cold plate in an open configuration and a second cold plate in a closed configuration, in accordance with various examples of the present disclosure.

FIG. 3 illustrates an example of a rotating cold plate assembly with a first cold plate in a closed configuration and a second cold plate in an open configuration, in accordance with various examples of the present disclosure.

FIG. 4 illustrates an example configuration of a rotating cold plate assembly with multiple cold plates plumbed in series, in accordance with various examples of the present disclosure.

FIG. 5 illustrates an example configuration of a rotating cold plate assembly with multiple cold plates plumbed in parallel, in accordance with various examples of the present disclosure.

FIG. 6 illustrates an example configuration of a rotating cold plate assembly with a single cold plate, in accordance with various examples of the present disclosure.

FIG. 7 illustrates an example method of replacing a TIM using a rotating cold plate assembly, in accordance with various examples of the present disclosure.

### DETAILED DESCRIPTION

### Overview

Replacing TIMs disposed between electronic circuits and cold plates can be a time consuming task, especially in the case of liquid-cooling cold plates. In order to gain access to the TIMs, often times, cold plates are completely removed from the associated systems (e.g., servers and computers). In the case of liquid-cooling cold plates, to remove the cold plates, a cooling medium (e.g., liquid, glycol and water) is often drained and influent and effluent lines that feed the cold plates are often disconnected from the cold plates. Not only is this time consuming, but it also has a high risk of spillage, which can damage components of the associated systems. While it is possible to keep the lines attached to the cold plates, doing so often requires the cold plates to remain covering the electronic components (e.g., hovering over them). Accordingly, access to the TIMs may be difficult without fully removing the cold plates from the associated systems.

Described herein is a cold plate assembly that includes a base configured to be mounted to a printed circuit board (PCB) to at least partially surround an electronic circuit disposed on the PCB. The cold plate assembly further includes a cold plate having a heat transfer surface configured to transfer heat from the electronic circuit to a cooling medium. The cold plate assembly also includes a hinge coupling the base and the cold plate. The hinge is configured to move the heat transfer surface into and away from thermal contact with the electronic circuit.

By coupling the base and the cold plate via a hinge, the cold plate is able to rotate away from the electronic circuit. In so doing, access to the electronic circuit and the heat transfer surface is easily achieved for installation, removal, and replacement of a TIM installed therebetween without necessitating removal of the cold plate. In addition, this enables, in the case of liquid-cooling cold plates, influent and effluent lines to remain attached to the cold plate while servicing and/or replacing the TIM.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example System

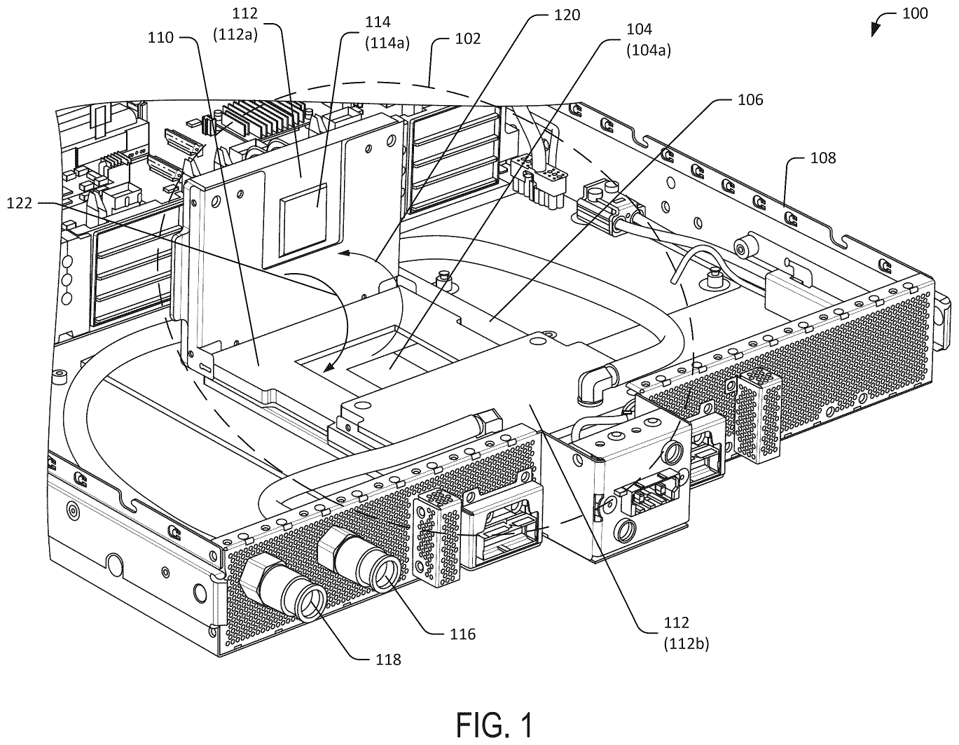

FIG. 1 illustrates an example of a system 100 with a rotating cold plate assembly 102. The system 100 may be any computing system (e.g., computer, server, rack component, and blade) with one or more electronic components 104 (e.g., circuits, processors, amplifiers, SOCs, processing units) that require heat transfer and/or heat dissipation (e.g., away from the system 100 or to another portion of the system 100). The rotating cold plate assembly 102 may be configured to interface with multiple electronic components 104 that are disposed proximate each other. For example, the electronic components 104 may be a central processing unit (CPU) and a graphics processing unit (GPU) that are disposed proximate each other on a PCB 106. Alternatively, the rotating cold plate assembly 102 may be configured to interface with a single electronic component 104.

Multiple rotating cold plate assemblies 102 may be used in the system 100 for respective groups of one or more electronic components 104 that are spaced apart from one another (e.g., on the PCB 106 or other PCBs). Thus, the system 100 may have any number of rotating cold plate assemblies 102. The PCB 106 may be attached to a frame 108 of the system 100 and may have any number of connectors, wires, and/or components other than the electronic components 104 necessitating heat transfer via cold plates.

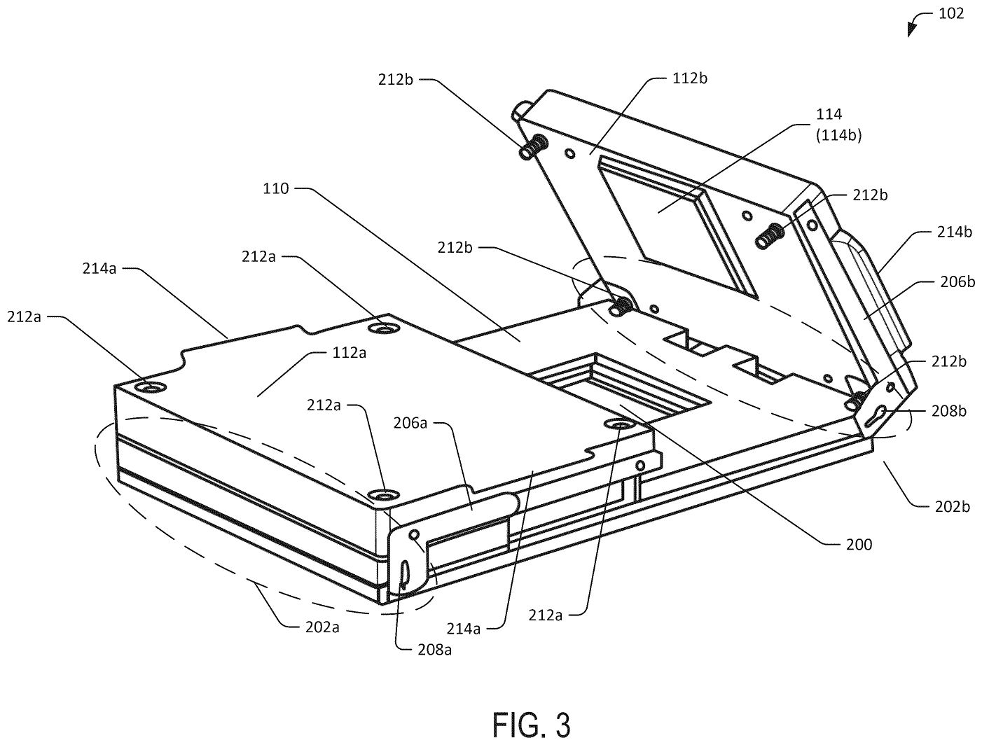

The rotating cold plate assembly 102 has a base 110 that is mounted (e.g., glued, bolted, screwed, or soldered) to the PCB 106 and/or the frame 108. The rotating cold plate assembly 102 has one or more cold plates 112 (e.g., 112a, 112b) that are configured to receive heat from the electronic components 104 via respective heat transfer surfaces 114 (e.g., 114a, 114b (shown in FIG. 3)).

The cold plates 112 are configured to transfer heat to a cooling medium such as air or a liquid. In the case of air, the cold plates 112 may be heat sinks (e.g., metal structures with fins). In the case of a liquid, the cold plates 112 may be liquid heat exchangers with one or more holes, tubes, or cavities formed therein. In the system 100, the cold plates 112 are configured for liquid cooling.

Depending upon implementation, there may be any number of cold plates 112 attached to the base 110. In the system 100, there are two electronic components 104 (104a, 104b) in close proximity to one another (e.g., a CPU and a GPU). Electronic component 104b is arranged underneath the cold plate 112b. (FIG. 3 shows an arrangement in which electronic component 104b is exposed) Accordingly, the rotating cold plate assembly 102 has the cold plate 112a configured to interface with electronic component 104a and the cold plate 112b configured to interface with electronic component 104b. As an alternative, a single cold plate 112 may be used that has multiple heat transfer surfaces 114 disposed thereon.

In some implementations, there may only be a single electronic component 104 necessitating heat transfer in a specific area of the system 100. In such cases, there may only be a single cold plate 112 attached to the base 110 with a single heat transfer surface 114. A separate rotating cold plate assembly 102 may be used for other electronic components 104 of the system 100.

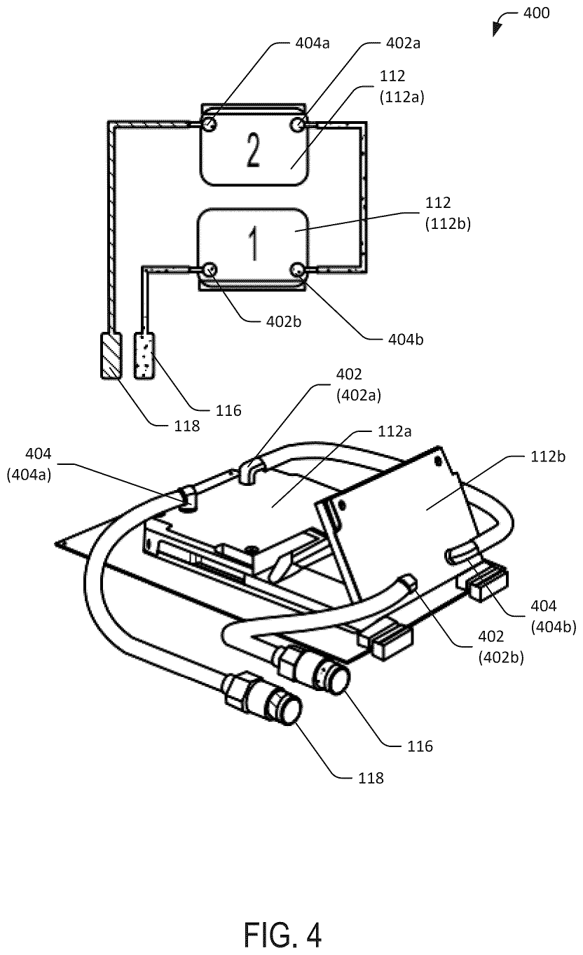

Because the rotating cold plate assembly 102 in the illustrated example is configured for liquid cooling, the system 100 contains a system influent port 116 and a system effluent port 118 configured to transfer a liquid cooling medium to and from the cold plates 112 via tubing or piping. The tubing or piping connects the system influent port 116 and the system effluent port 118 to influent and effluent ports of the cold plates 112. Example plumbing configurations are discussed further in regard to FIGS. 4-6. Regardless of how the rotating cold plate assembly 102 is plumbed, the system influent port 116 and the system effluent port 118 may be configured to interface with an external chiller system. In some implementations, however, the chiller system be a part of the system 100. In such cases, the system influent port 116 and the system effluent port 118 may be portions of the chiller system or not exist (e.g., the piping may be directly connected to the chiller system).

The cold plate 112a is able to rotate away from the base 110 in an opening direction 120 or towards the base in a closing direction 122. The cold plate 112b is also able to rotate away from the base 110 in an opening direction and in a closing direction, which may be the same or different from the opening direction 120 and the closing direction 122. In the illustrated example, the cold plate 112a is configured to rotate in an opposite direction as cold plate 112b. That is, the cold plate 112a and cold plate 112b are configured to open like cabinet doors (e.g., away from each other) thereby exposing the electronic components 104a, 104b. In some implementations, the cold plates 112a, 112b may be configured to rotate in similar directions (e.g., hinged on a same side of the base 110). In other implementations, the cold plates 112a, 112b may be combined into a single cold plate 112 hinged on a side of the base 110. In such implementations, the cold plate 112 may contain multiple heat transfer surfaces 114 (e.g., one for each electronic component 104). If there is only a single electronic component 104 to be cooled by the cold plate 112, then a single heat transfer surface 114 may be used (e.g., the rotating cold plate assembly 102 would consist of the base 110 and a single cold plate 112 attached thereto). As discussed further below, the cold plate(s) 112 are attached to the base 110 via respective hinges.

### Example Cold Plate Assembly

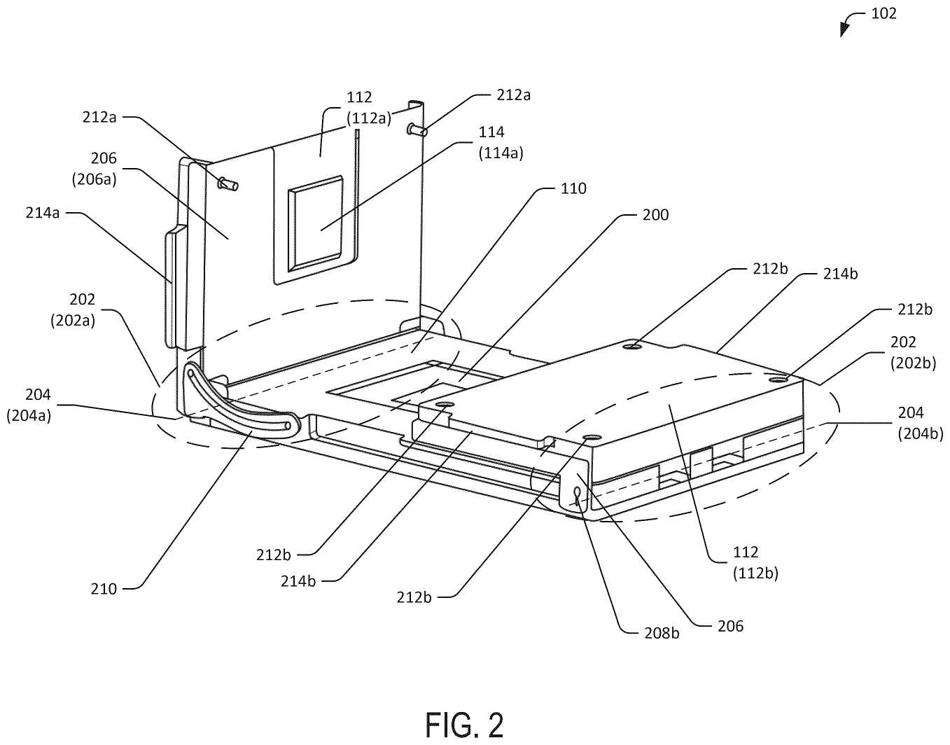

FIG. 2 illustrates an example of the rotating cold plate assembly 102 with the cold plate 112a in an open configuration and the cold plate 112b in a closed configuration. The open configuration means that the respective cold plate 112 is rotated away from the base 110 (e.g., such that the respective heat transfer surface 114 is no longer parallel to a top surface of the base 110). The closed configuration means that the respective cold plate 112 is rotated towards the base 110 (e.g., such that the respective heat transfer surface 114 is parallel to the top surface of the base 110). The respective cold plate 112 may be at least 90 degrees from the base 110 in the open configuration. By having the respective cold plate 112 at least 90 degrees from the base 110, easy access to the respective heat transfer surface 114 and the associated electronic component 104 is ensured. Furthermore, the respective cold plate 112 may be less likely to fall back into the closed configuration.

The base 110 may be formed as a plate-like structure. That is, the base 110 may have an upper surface that is planar and a lower surface that is planar, with the upper surface being substantially parallel to the lower surface. Furthermore, the cold plates 112 may be formed as plate-like structures with planar upper and lower surfaces that are substantially parallel to each other. Upper and lower are generally in reference to the PCB 106. Accordingly, an upper surface would be further away from the PCB 106 than a lower surface when the rotating cold plate assembly 102 is mounted to the PCB 106.

The heat transfer surfaces 114 may be planar and offset from the lower surfaces of their associated cold plates 112. A positive offset means that a heat transfer surface 114 is raised relative to the lower surface of the cold plate 112 (e.g., heat transfer surface 114a). A negative offset means that the heat transfer surface 114 is indented relative to the lower surface of the cold plate 112. Depending upon a height of the associated electronic component 104 and a thickness of the base 110, a positive or a negative offset (or a zero offset) may be used. Different offsets may be used for different cold plates 112.

Formed within the base 110 is a cutout 200 (e.g., the base 110 defines the cutout 200). The cutout 200 may be configured to receive the electronic component 104. The cutout 200 may go through the base 110 and may surround one or more sides of the electronic component 104. Accordingly, the cutout 200 may have a shape that corresponds to a perimeter of the electronic component(s) 104. The cutout 200 may be larger than the perimeter of the electronic component(s) 104 to allow for tolerances, fitting, space, etc. Although shown as being a complete perimeter (e.g., having four sides), the cutout 200 may be configured to surround less than four sides of the electronic component 104. For example, the cutout 200 may be a slot or configured to be adjacent to a single side of the electronic component 104. In such implementations, the base 110 may be a much smaller structure disposed beside the electronic component 104.

The cold plates 112 are connected to the base 110 via respective hinges 202 (202a, 202b). In the illustrated example, the hinges 202 are disposed on opposite sides of the base 110. In some implementations, the hinges 202 may be disposed on a same side of the base 110. In other implementations, a single hinge 202 may be used for multiple cold plates 112 or a single cold plate 112 may be used for multiple electronic components 104.

Each of the hinges 202 is configured to allow the associated cold plate 112 to rotate along a rotation axis 204 (204a, 204b). The rotation axis 204 is generally parallel to the heat transfer surface 114. The hinge 202 may also allow the cold plate 112 to translate relative to the rotation axis 204 when the rotation axis 204 is fixed relative to the base 110 or the rotation axis 204 to translate relative to the base 110 when the rotation axis 204 is fixed relative to the cold plate 112. For example, in the illustrated example, the hinge 202a is configured with the rotation axis 204a fixed relative to the base 110. The hinge 202a may also be configured to allow the cold plate 112a to translate relative to the rotation axis 204a. In other implementations, the hinge 202 may be configured with the rotation axis 204 fixed relative to the cold plate 112. In such implementations, the hinge 202 may also be configured to allow the cold plate 112 along with the rotation axis 204 to translate relative to the base 110. Although translation is not necessary, it may enable the cold plate 112 (and thus the rotating cold plate assembly 102) to adapt to different heights of electronic components, adapt to tolerances of heights and thicknesses, and allow for even compression of TIMs.

The hinge 202 may comprise at least one plate 206 mounted to either the cold plate 112 or the base 110. The plate 206 may wrap around two or more sides of the mounted structure. For example, in the illustrated example, the plate 206 wraps around edges of the cold plate 112b. In other words, the cold plate 112 may fit within a cradle formed by the plate 206. The plate 206 may extend lower than the lower surface of the cold plate 112b to enable a pin (e.g., through both plates 206 and the base 110), screws (e.g., one for each side of the cold plate 112), or other fixtures to rotatably connect the plate 206 and the base 110. In some implementations, the plate 206 may comprise a pair of plates mounted to respective sides of the cold plate 112. The plate(s) 206 may be glued, screwed, or otherwise adhered to the cold plates 112. In some implementations, the plate(s) 206 (at least the portion that extends lower than the lower surface of the cold plate 112b) may be formed as parts of the cold plates 112.

If the hinge 202 is configured only for rotation, holes may be formed in the plate 206 and the base 110 (if the plate 206 is mounted to the cold plate 112, as shown). For example, the holes may be formed in the portion of the plate 206 that extends lower than the lower surface of the cold plate 112. If the hinge 202 is configured for translation, the plate 206 may have a slot formed therein (as shown).

Any number of variations of the hinge 202 may be used without departing from the scope of the disclosure. For example, the hinge 202 may be any structure that allows the rotation and optionally the translation discussed above. The hinge 202 may be mounted to any side of the cold plate 112 or any side of the base 110. Any of the holes may be slotted to allow for translation. The illustrated example is just one way of achieving the hinge 202. The hinges 202 (e.g., for the plurality of cold plates 112) may be similar or different, however, they are generally configured to allow both cold plates 112 to rotate and/or translate as discussed above. It should be recognized that many different arrangements of the hinges 202 may be used to facilitate the rotation and translation of the cold plates 112 relative to the base 110.

The rotating cold plate assembly 102 may also contain a rotation guide 210 mounted between the cold plate 112 and the base 110. The rotation guide 210 is configured to guide the rotation of the cold plate 112 and may also have detents for the open and closed configurations. The rotation guide 210 may be implemented on any number of the cold plates 112 and on two sides of the cold plate 112.

In order to maintain the closed configuration and to ensure good thermal conductivity between the electronic components 104 and the heat transfer surfaces 114, the cold plates 112 may have respective cold plate fixing portions 212. The cold plate fixing portions 212 are configured to maintain a closed configuration of the rotating cold plate assembly 102 (e.g., keep the cold plates 112 from rotating and/or translating). Further, the cold plate fixing portions 212 may be configured to clamp or otherwise compress the TIMs between the heat transfer surfaces 114 and the associated electronic components 104. For example, the cold plate fixing portions 212 may comprise arrays of through holes in the cold plates 112 and associated threaded holes in the base 110. Screws or bolts may then be used to secure the cold plates 112 to the base 110 via the cold plate fixing portions 212. The cold plate fixing portions 212 may also contain latches, clamps, or any number of other fixing mechanisms. The securing/engagement of the cold plate fixing portions 212 may cause the cold plates 112 to translate relative to their respective rotation axes 204 (e.g., due to squish of TIMs).

The cold plates 112 may also contain lifting portions 214. The lifting portions 214 are configured to facilitate the rotation of the cold plates 112 from a user. The lifting portions 214 may comprise handles or other protrusions on one or more sides of the cold plates 112 that are configured to be grabbed by a user to facilitate the rotation and/or translation of the cold plates 112.

FIG. 3 illustrates an example of the rotating cold plate assembly 102 with the cold plate 112b in a partially open configuration and the cold plate 112a in a closed configuration. As the parts are similar to those discussed in regard to FIG. 2, the detailed description of such parts will not be repeated here.

The cold plate 112b may be rotated, for example, at least 90 degrees relative to the base 110. It should be noted that, in the illustrated example, the cold plate 112b is not fully rotated/opened (e.g., it is less than 90 degrees from the base 110). As discussed above, rotating at least 90 degrees may allow the cold plate 112b to stay in the open configuration 302 (e.g., gravity will not pull it back towards the closed configuration 300). The rotation guide 210 (shown in FIG. 2) may also be implemented, which may facilitate holding the cold plate 112b in the open configuration, even if the cold plate 112b is not configured to rotate a full 90 degrees or more. In other words, the open configuration 302 may be less than 90 degrees with a detent or other mechanism to hold it in such a position, or at or more than 90 degrees with just the hinge 202b.

It should be noted that the plates 206 in the illustrated example comprise plates mounted on each side of the respective cold plates 112 (as opposed to a single plate 206 for each cold plate 112). Again, any number of configurations of the hinges 202 and plates 208 may be used without departing from the scope of this disclosure.

### Example Configurations

FIG. 4 illustrates an example of a configuration 400 of a rotating cold plate assembly with multiple cold plates plumbed in series. The configuration 400 is generally configured for multiple electronic components 104 (e.g., multiple cold plates 112).

The configuration 400 includes the system influent port 116 and the system effluent port 118. Each of the cold plates 112 has corresponding influent ports 402 (404a, 404b) and effluent ports 404 (404a, 404b). In the configuration 400, the system influent port 116 is connected to the influent port 402b, the effluent port 404b is connected to the influent port 402a, and the effluent port 404a is connected to the system effluent port 118. The order of the influent and effluent ports may be reversed without departing from the scope of this disclosure. In other words, the cold plate 112a may receive the liquid from the system influent port 116 and the cold plate 112b may send the warmer liquid to the system effluent port 118. Furthermore, the relative sides of the ports relative to the cold plates 112 may be switched without departing from the scope of this disclosure.

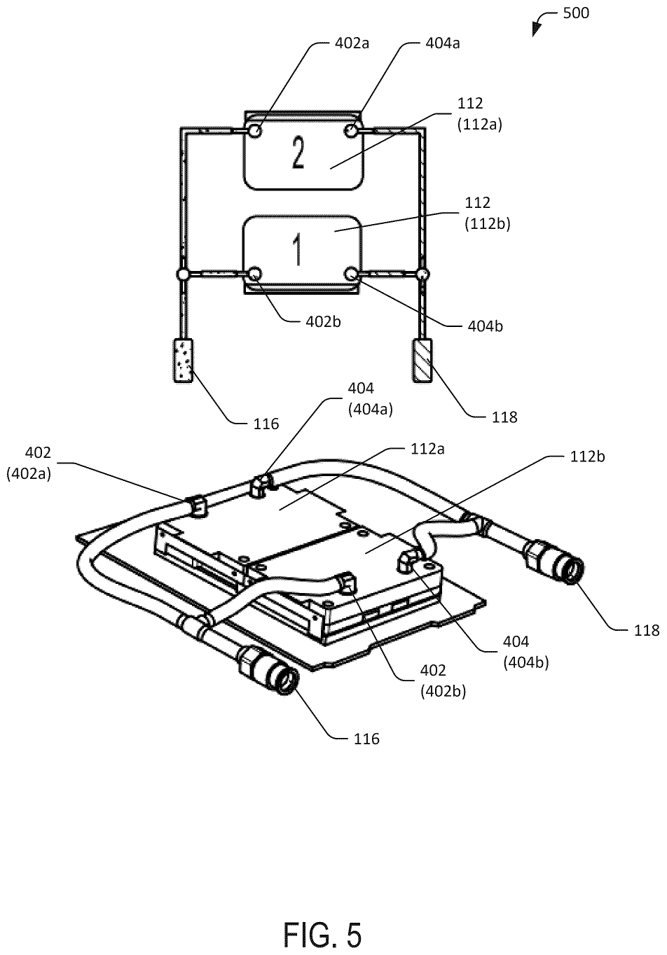

FIG. 5 illustrates an example of a configuration 500 of a rotating cold plate assembly with multiple cold plates plumbed in parallel. The configuration 500 is generally configured for multiple electronic components 104 (e.g., multiple cold plates 112).

The configuration 500 includes the system influent port 116 and the system effluent port 118. Each of the cold plates 112 has corresponding influent ports 402 and effluent ports 404. In the configuration 500, the system influent port 116 is connected to both the influent port 402a and the influent port 402b, and both the effluent port 404a and the effluent port 404b are connected to the system effluent port 118. The order of the influent and effluent ports may be reversed without departing from the scope of this disclosure. Furthermore, the relative sides of the ports relative to the cold plates 112 may be switched without departing from the scope of this disclosure.

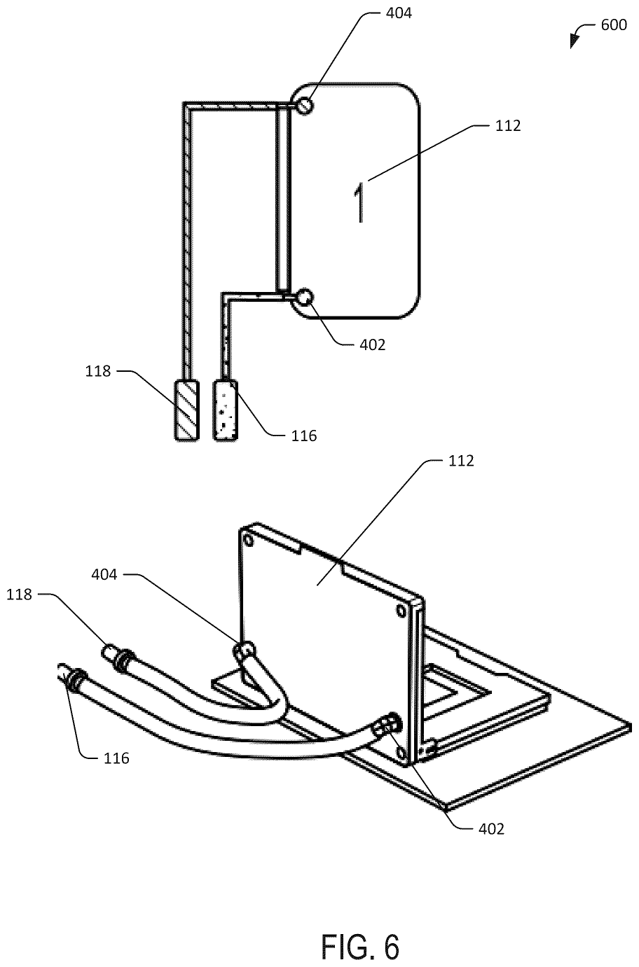

FIG. 6 illustrates an example of a configuration 600 of a rotating cold plate assembly with a single cold plate. The configuration 600 is generally configured for one or more electronic components 104 (e.g., one or more heat transfer surfaces 114).

In the configuration 600, the system influent port 116 is connected to the influent port 402 and the effluent port 404 is connected to the system effluent port 118. If there is a single electronic component 104, then the cold plate 112 may contain a single heat transfer surface 114.

If there are multiple electronic components 104 (e.g., two adjacent electronic components 104), then the cold plate 112 may contain multiple heat transfer surfaces 114 (e.g., one for each electronic components 104). The heat transfer surfaces 114 may have different offsets from one another to accommodate varying thicknesses of the electronic components 104.

### Example Method

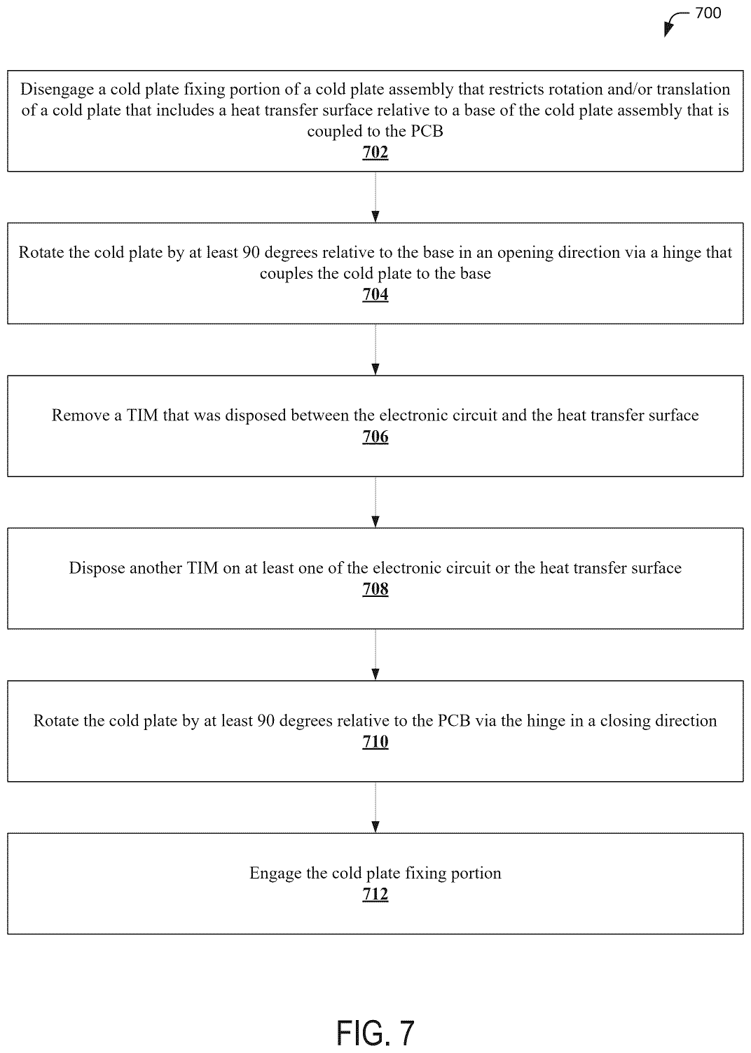

FIG. 7 illustrates an example of a method 700 of replacing a TIM disposed between a heat transfer surface of a rotating cold plate assembly and an electronic circuit or component. The method 700 may be used on any of the above systems, components, or configurations. In a multi-electronic component configuration, the method 700 may be repeated for other cold plates/components.

At 702, a cold plate fixing portion of a cold plate assembly that restricts rotation and/or translation (e.g., movement) of a cold plate that includes a heat transfer surface is disengaged relative to a base of the cold plate assembly that is coupled to the PCB. For example, the cold plate fixing portion 212 may be disengaged from an associated cold plate 112. When implemented as screws between the cold plate 112 and the base 110, the disengaging may involve completely loosening or removing the screws.

At 704, the cold plate is rotated by, for example, at least 90 degrees relative to the base in an opening direction via a hinge that couples the cold plate to the base. The rotating in the opening direction separating the TIM from at least one of an associated electronic circuit or the heat transfer surface. For example, the cold plate 112 may be rotated in the opening direction 120 to produce the open configuration 302. When initiating the rotation, the TIM may separate from the electronic component 104 and/or the heat transfer surface 114 of the cold plate 112. It should be noted that the cold plate may not be rotated by at least 90 degrees if a holding device (e.g., the rotation guide 210) is used to keep the cold plate 112 from returning to the closed configuration 300.

At 706, the TIM is removed. Any method of removing the TIM (e.g., scraping, solvent, blades, heat, etc.) may be used.

At 708, another TIM is disposed on at least one of the electronic circuit or the heat transfer surface 114. For example, a new TIM may be disposed on the heat transfer surface 114 and/or the electronic component 104.

At 710, the cold plate is rotated by, for example, at least 90 degrees relative to the PCB via the hinge in a closing direction. The rotating in the closing direction 122 causing the other TIM to engage the electronic component 104 and the heat transfer surface 114. For example, the cold plate 112 may be rotated in the closing direction 122 to produce the closed configuration 300. The closed configuration 300 involves the TIM engaging both the heat transfer surface 114 and the electronic component 104. The closed configuration 300 may involve the cold plate 112 to be generally parallel to a top surface of the electronic component 104.

At 712, the cold plate fixing portion 212 is engaged. For example, the cold plate fixing portion 212 may be engaged from the cold plate 112. When implemented as screws between the cold plate 112 and the base 110, the engaging may involve tightening the screws.

### EXAMPLES

Example 1a: A cold plate assembly comprising: a base configured to be mounted to a printed circuit board (PCB) to at least partially surround an electronic circuit disposed on the PCB; a cold plate comprising a heat transfer surface configured to transfer heat from the electronic circuit to a cooling medium; and a hinge coupling the base and the cold plate, and configured to move the heat transfer surface into and away from thermal contact with the electronic circuit.

Example 2a: The cold plate assembly of example 1a, wherein: the base further comprises a base top surface and a base bottom surface; the base defines a cutout extending from the base top surface to the base bottom surface; and the cutout is configured to receive the electronic circuit.

Example 3a: The cold plate assembly of examples 1a or 2a, wherein: the heat transfer surface is planar; the hinge is further configured to allow the cold plate to pivot relative to the base along a rotation axis; and the rotation axis is substantially parallel to the heat transfer surface.

Example 4a: The cold plate assembly of any preceding example, wherein the hinge includes a sliding hinge configured to allow the cold plate to pivot relative to the base and translate along a translation axis.

Example 5a: The cold plate assembly of any preceding example, wherein: the cold plate further includes a cold plate bottom surface; the heat transfer surface is planar; and the heat transfer surface is offset from the cold plate bottom surface.

Example 6a: The cold plate assembly of example 5a, wherein: the cold plate further includes a cold plate top surface; and the cold plate bottom surface is arranged between the heat transfer surface and the cold plate top surface.

Example 7a: The cold plate assembly of any preceding example, further comprising a cold plate fixing portion configured to, when engaged, restrict movement of the cold plate relative to the base.

Example 8a: The cold plate assembly of any preceding example, wherein the hinge is further configured to allow the cold plate to rotate at least 90 degrees relative to the base.

Example 9a: The cold plate assembly of any preceding example, wherein: the cooling medium is air; the cold plate comprises a heat sink; and the cold plate is further configured to transfer the heat from the electronic circuit to the air via the heat sink.

Example 10a: The cold plate assembly of any preceding example, wherein: the cooling medium is a liquid; the cold plate includes a heat exchanger having one or more tubes or cavities formed in the cold plate; and the cold plate is further configured to transfer the heat from the electronic circuit to the liquid via the heat exchanger.

Example 11a: The cold plate assembly of any preceding example, wherein the heat transfer surface has a shape that corresponds to a shape of the electronic circuit.

Example 12a: The cold plate assembly of any preceding example, wherein the hinge comprises: hinge plates connected to respective sides of one of the base or the cold plate; through holes disposed through a rotation end of the base or the cold plate that does not have the hinge plates connected thereto; and a pin disposed through the hinge plates and the through holes.

Example 13a: The cold plate assembly of example 12a, wherein: the hinge plates are connected to the cold plate; the cold plate further includes a cold plate bottom surface; and the hinge plates extend past the cold plate bottom surface.

Example 14a: The cold plate assembly of examples 12a or 13a, wherein: the hinge plates includes slots; and the pin is disposed within the slots of the hinge plates.

Example 15a: The cold plate assembly of any preceding example, wherein: the electronic circuit is a first electronic circuit; the base further includes a base top surface and a base bottom surface; the base defines a cutout extending from the base top surface to the base bottom surface; the cutout is configured to at least partially surround the first electronic circuit and a second electronic circuit disposed on the PCB; the heat transfer surface is configured to transfer heat from the first electronic circuit and the second electronic circuit; and the hinge is configured to move the heat transfer surface into and away from thermal contact with the first electronic circuit and the second electronic circuit.

Example 16a: The cold plate assembly of any preceding example, wherein: the electronic circuit is a first electronic circuit, the cold plate is a first cold plate, the heat transfer surface is a first heat transfer surface and the hinge is a first hinge; the base is configured to at least partially surround the first electronic circuit and a second electronic circuit disposed on the PCB; the cold plate assembly further includes a second cold plate, the second cold plate having a second heat transfer surface configured to transfer heat from the second electronic circuit to the cooling medium; and the cold plate assembly further includes a second hinge connecting the base and the second cold plate, and configured to move the second heat transfer surface into and away from thermal contact with the second electronic circuit.

Example 17a: The cold plate assembly of example 16a, wherein: the first hinge has a first rotation axis; the second hinge has second rotation axis; and the first rotation axis and the second rotation axis are substantially parallel to one another.

Example 18a: The cold plate assembly of examples 16a or 17a, wherein the first hinge and the second hinge are disposed on opposing ends of the base.

Example 19a: The cold plate assembly of examples 16a, 17a, or 18a, wherein: the cooling medium is a liquid; the first cold plate includes a first heat exchanger; the second cold plate includes a second heat exchanger; and the first heat exchanger and the second heat exchanger are configured to be plumbed in parallel with one another.

Example 20a: The cold plate assembly of examples 16a, 17a, or 18a, wherein: the cooling medium is a liquid; the first cold plate includes a first heat exchanger; the second cold plate includes a second heat exchanger; and the first heat exchanger and the second heat exchanger are configured to be plumbed in series with one another.

Example 1b: A system comprising: a printed circuit board (PCB); an electronic circuit disposed on the PCB; the cold plate assembly of any of examples 1a-20a; and a thermal interface material disposed between the heat transfer surface and the electronic circuit.

Example 1c: A method of operating the cold plate assembly of any of examples 1a-20a, the method comprising: operating the hinge to move the heat transfer surface away from thermal contact with the electronic circuit; arranging a thermal interface material on at least one of the heat transfer surface of the cold plate and the electronic circuit; and operating the hinge to move the heat transfer surface into thermal contact with the electronic circuit.

Example 1d: A method of replacing a thermal interface material (TIM) disposed between an electronic circuit of a printed circuit board (PCB) and a heat transfer surface of a cold plate assembly that is mounted to the PCB, the method comprising: disengaging a cold plate fixing portion that restricts rotation and/or translation of a cold plate that includes the heat transfer surface relative to a base of the cold plate assembly that is coupled to the PCB; rotating the cold plate by at least 90 degrees relative to the PCB in an opening direction via a hinge that couples the cold plate to the base, the rotating in the opening direction effective to separate the TIM from at least one of the electronic circuit or the heat transfer surface; removing the TIM; disposing another TIM to at least one of the electronic circuit or the heat transfer surface; rotating the cold plate by at least 90 degrees relative to the PCB via the hinge in a closing direction, the rotating in the closing direction effective to cause the other TIM to engage the electronic circuit and the heat transfer surface; and engaging the cold plate fixing portion.

### CONCLUSION

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The various embodiments were chosen and described in order to best explain the principles of the invention and the practical application, and to enable others of ordinary skill in the art to understand the invention for various embodiments with various modifications as are suited to the particular use contemplated.

What is claimed is:

1. A rotating cold plate assembly comprising:
a base configured to be mounted to a printed circuit board (PCB) to at least partially surround an electronic circuit disposed on the PCB;
a cold plate having a heat transfer surface configured to transfer heat from the electronic circuit to a cooling medium; and
a hinge coupling the base and the cold plate configured to move the heat transfer surface into and away from thermal contact with the electronic circuit.

2. The rotating cold plate assembly of claim 1, wherein:
the base further includes a top surface of the base and a lower surface of the base;
the base defines a cutout extending from the top surface of the base to the lower surface of the base; and
the cutout is configured to receive the electronic circuit.

3. The rotating cold plate assembly of claim 1, wherein:
the hinge is further configured to allow the cold plate to rotate relative to the base along a rotation axis; and
the rotation axis is substantially parallel to a top surface of the base.

4. The rotating cold plate assembly of claim 3, wherein the hinge is further configured to allow the cold plate to translate relative to the rotation axis.

5. The rotating cold plate assembly of claim 1, wherein:
the cold plate further includes a lower surface of the cold plate;
the heat transfer surface is planar; and
the heat transfer surface is offset from the lower surface of the cold plate.

6. The rotating cold plate assembly of claim 5, wherein:
the cold plate further includes a top surface of the cold plate; and
the lower surface of the cold plate is arranged between the heat transfer surface and the top surface of the cold plate.

7. The rotating cold plate assembly of claim 1, further comprising a cold plate fixing portion configured to, when engaged, restrict movement of the cold plate relative to the base.

8. The rotating cold plate assembly of claim 1, wherein the hinge is further configured to allow the cold plate to rotate at least 90 degrees relative to the base.

9. The rotating cold plate assembly of claim 1, wherein:
the cooling medium is air;
the cold plate includes a heat sink; and
the cold plate is further configured to transfer the heat from the electronic circuit to the air via the heat sink.

10. The rotating cold plate assembly of claim 1, wherein:
the cooling medium is a liquid;
the cold plate includes one or more tubes or cavities formed in the cold plate; and
the cold plate is further configured to transfer the heat from the electronic circuit to the liquid via the one or more tubes or cavities.

11. The rotating cold plate assembly of claim 1, wherein the heat transfer surface has a shape that corresponds to a shape of the electronic circuit.

12. The rotating cold plate assembly of claim 1, wherein the hinge includes:
at least one plate connected to one of the base or the cold plate;
holes disposed in the base or the cold plate that does not have the plates connected thereto; and
at least one pin or screw disposed through the plate and the holes.

13. The rotating cold plate assembly of claim 12, wherein:
the plate is connected to the cold plate;
the cold plate further includes a lower surface of the cold plate; and
the plate extends past the lower surface of the cold plate.

14. The rotating cold plate assembly of claim 12, wherein:
the plate includes slots; and
the pin or screw is disposed within the slots of the plate.

15. The rotating cold plate assembly of claim 1, wherein:
the electronic circuit is a first electronic circuit;
the base further includes a top surface of the base and a lower surface of the base;
the base defines a cutout extending from the top surface of the base to the lower surface of the base;
the cutout is configured to at least partially surround the first electronic circuit and a second electronic circuit disposed on the PCB;
the heat transfer surface is configured to transfer heat from the first electronic circuit and the second electronic circuit; or
the cold plate further contains another heat transfer surface configured to transfer heat from the second electronic circuit; and
the hinge is configured to move the heat transfer surface into and away from thermal contact with the first electronic circuit and the second electronic circuit.

16. The rotating cold plate assembly of claim 1, wherein:
the electronic circuit is a first electronic circuit, the cold plate is a first cold plate, the heat transfer surface is a first heat transfer surface and the hinge is a first hinge;
the base is configured to at least partially surround the first electronic circuit and a second electronic circuit disposed on the PCB;
the cold plate assembly further includes a second cold plate, the second cold plate having a second heat transfer surface configured to transfer heat from the second electronic circuit to the cooling medium; and
the cold plate assembly further includes a second hinge connecting the base and the second cold plate, and configured to move the second heat transfer surface into and away from thermal contact with the second electronic circuit.

17. The rotating cold plate assembly of claim 16, wherein:
the first hinge has a first rotation axis;
the second hinge has second rotation axis; and
the first rotation axis and the second rotation axis are substantially parallel to one another.

18. The rotating cold plate assembly of claim 16, wherein the first hinge and the second hinge are disposed on opposing sides of the base.

19. A system comprising:
a printed circuit board (PCB);
an electronic circuit disposed on the PCB; and
a cold plate assembly including:
a base mounted to the PCB that at least partially surrounds the electronic circuit disposed on the PCB;
a cold plate having a heat transfer surface configured to transfer heat from the electronic circuit to a cooling medium; and
a hinge connecting the base and the cold plate, and configured to move the heat transfer surface into and away from thermal contact with the electronic circuit.

20. A method of operating a cold plate assembly, the cold plate assembly having a base mounted to a printed circuit board (PCB) to at least partially surround an electronic circuit disposed on the PCB, a cold plate having a heat transfer surface configured to transfer heat from the electronic circuit to a cooling medium, and a hinge connecting the base and the cold plate, the method comprising:
operating the hinge to move the heat transfer surface away from thermal contact with the electronic circuit;
arranging a thermal interface material on at least one of the heat transfer surface of the cold plate and the electronic circuit; and
operating the hinge to move the heat transfer surface into thermal contact with the electronic circuit.
